(19) United States
(12) Patent Application Publication
(10) Pub. No.: US 2025/0293104 A1
(43) Pub. Date: Sep. 18, 2025

(54) PACKAGE ASSEMBLY AND MANUFACTURING METHOD THEREOF

(71) Applicant: Taiwan Semiconductor Manufacturing Company, Ltd., Hsinchu (TW)

(72) Inventors: Pu Wang, Hsinchu City (TW); Li-Hui Cheng, New Taipei City (TW); Ying-Ching Shih, Hsinchu City (TW)

(73) Assignee: Taiwan Semiconductor Manufacturing Company, Ltd., Hsinchu (TW)

(21) Appl. No.: 18/605,724

(22) Filed: Mar. 14, 2024

(51) Int. Cl. H01L 23/10; H01L 21/52; H01L 23/053; H01L 23/538

(52) U.S. Cl. CPC H01L 23/10; H01L 21/52; H01L 23/053; H01L 23/5385

(57) ABSTRACT

A package assembly includes a device package including an encapsulated die and an interposer disposed below the encapsulated die, a package substrate disposed below the device package and electrically coupled to the encapsulated die through the interposer, and a support structure disposed on the package substrate. The device package is housed in a cavity formed by the support structure and the support structure. The support structure includes a lid portion made of a material transparent to a radiation, a ring portion between the lid portion and the package substrate, and a releasable adhesive layer being response to the radiation.

### BACKGROUND

In the packaging of integrated circuits, semiconductor dies may be stacked through bonding, and may be bonded to other package components such as interposers and package substrates. The resulting semiconductor packages are known as three-dimensional integrated circuits (3DICs). However, warpage, coplanarity, delamination, and heat dissipation issues are challenges in the 3DICs. As a result, there is continuous effort in developing new mechanisms of forming semiconductor packages with better reliability and performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1E are schematic cross-sectional views of various stages of manufacturing a package assembly, in accordance with some embodiments.

FIGS. 2A-2C are schematic cross-sectional views showing the variations of the structure in the dashed box A of FIG. 1E, in accordance with some embodiments.

FIG. 3A is a schematic cross-sectional view showing that a de-bonding process is performed on the package assembly of FIG. 1E, in accordance with some embodiments.

FIG. 3B is a schematic and partial top-down view of de-bonded marks, in accordance with some embodiments.

FIGS. 4A and 4C are schematic cross-sectional views of various stages of manufacturing a package assembly, in accordance with some embodiments.

FIG. 4B is a schematic top-down view showing a possible distribution area of the release adhesive layer on the third package component, in accordance with some embodiments.

FIGS. 5A and 5B are schematic cross-sectional views showing the variations of the structure in the dashed box B of FIG. 4C, in accordance with some embodiments.

FIG. 6 is a schematic cross-sectional view showing that a de-bonding process is performed on the package assembly of FIG. 4C, in accordance with some embodiments.

FIGS. 7A-7B are schematic cross-sectional views of various stages of manufacturing a package assembly, in accordance with some embodiments.

FIG. 8 is a schematic cross-sectional view showing that a de-bonding process is performed on the package assembly of FIG. 7B, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In semiconductor industry, one or more device package(s) may be mounted on a package substrate to form a package assembly. In some cases, a stiffener ring is attached to the package substrate to constrain the package substrate and reduce warpage (e.g., caused by stress generated during processing steps or testing). However, for a package assembly having severe warpage, it is not enough to minimize the warpage by the stiffener ring along, and the candidate materials for the stiffener ring that meet the coefficient of thermal expansion (CTE) requirements and constrain the package substrate are limited. In some other cases, a lid is disposed over the stiffener ring for providing improved coplanarity as compared the package assembly having the stiffener ring alone. For example, the lid is fixed on the top of the stiffener ring using a fixing component such as screw or the like. However, this approach induces local deformation on the package substrate and reduces throughput of the package assembly. In some cases, a thermal interface material (TIM) is formed between the lid and the device package for heat dissipation. However, since the device package and the lid are formed of different materials having mismatched CTE, the device package and the lid may experience significantly different dimensional change under temperature change which may lead to the delamination/crack of TIM. In addition, the candidate materials for the TIM that can meet the CTE requirements are limited. Moreover, the TIM may suffer from performance degradation after the subsequent processing and thermal cycling(s).

Embodiments discussed herein are to provide a package assembly including a support structure and a method for forming the same. The intermediate stages of forming the package assembly are illustrated, and the variations of the embodiments are discussed. According to various embodiments, the support structure includes a ring portion coupled to the package substrate and a lid portion overlying the ring portion. The ring and lid portions may be integratedly formed or may be temporarily coupled through a removable adhesive layer. In this manner, the package assembly may have improved coplanarity without using fixing components (e.g., a screw or the like), thereby increasing product throughput and reducing manufacturing cost. At least the lid portion of the support structure may be made of a material transparent to a radiation used in the subsequently-performed de-bonding process. The removable adhesive layer having sufficient response to the radiation may lose its adhesiveness when exposed to the radiation. In this manner, the support structure may be easily removed by de-bonding the removable adhesive layer. The removable adhesive layer and the material(s) of the support structure may be tailored for the subsequently-performed de-bonding process in order to meet various de-bonding process requirements of customers. It should be noted that throughout the various views and illustrative embodiments, like reference numbers are used to designate like elements.

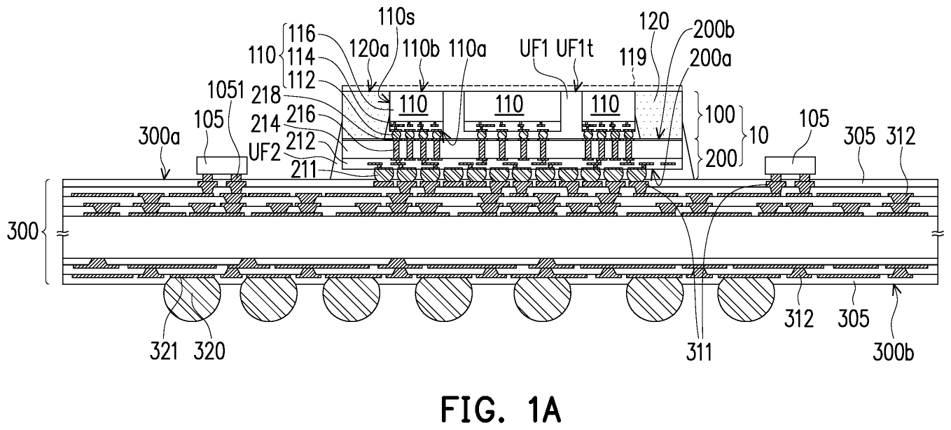

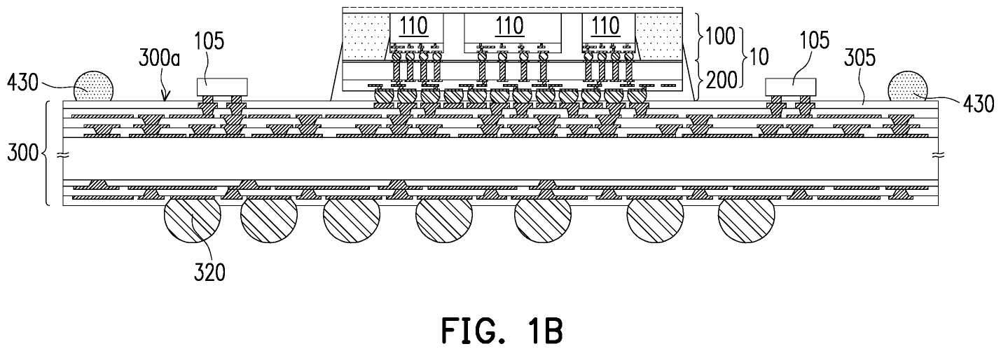

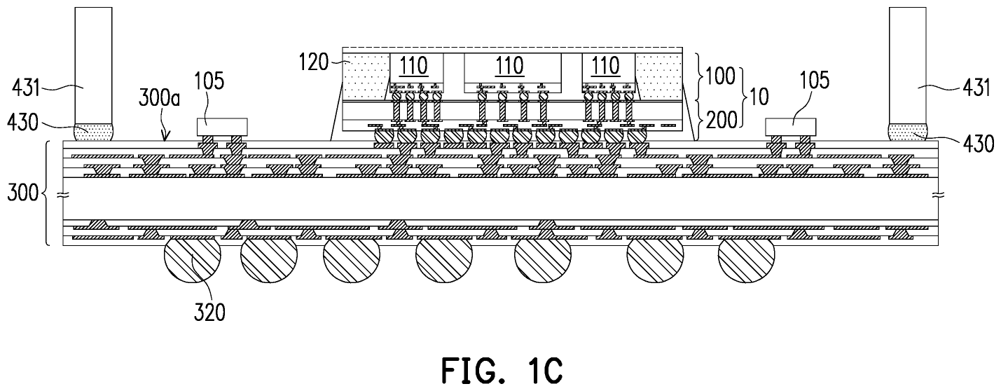

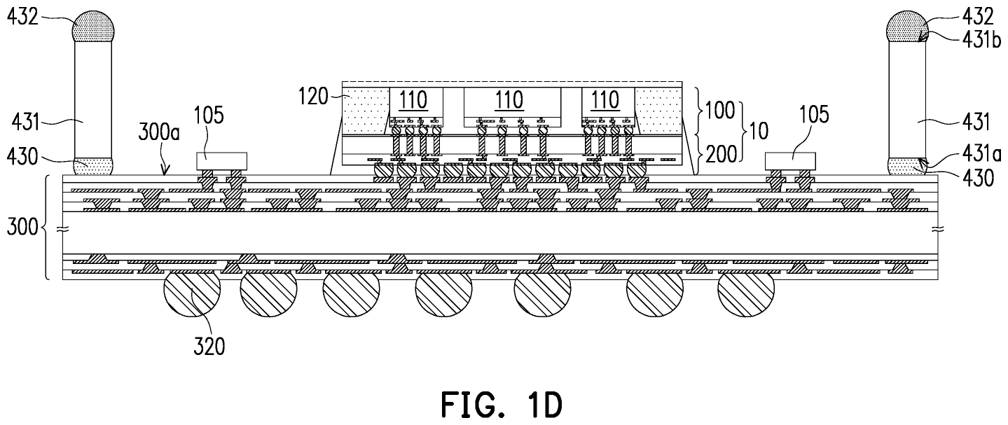

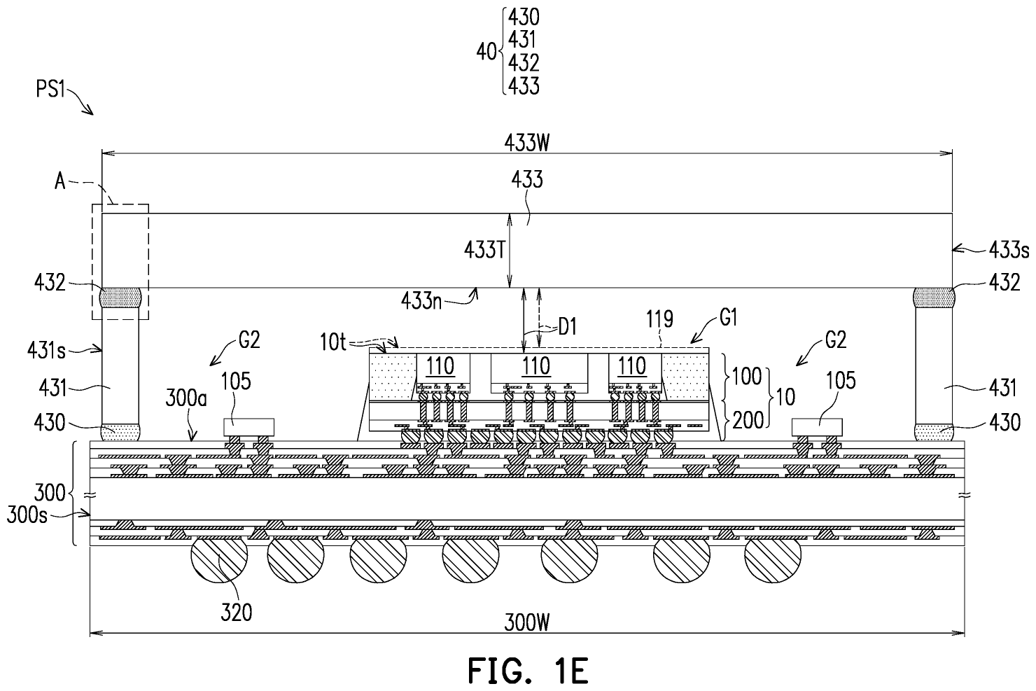

FIGS. 1A-1E are schematic cross-sectional views of various stages of manufacturing a package assembly, in accordance with some embodiments. Referring to FIG. 1A, a first package component 100 may be disposed on a second package component 200. A stack of the first package component 100 and the second package component 200 may be mounted on a third package component 300 with the second package component 200 interposed between the first package component 100 and the third package component 300. In some embodiments, the first package component 100 and the second package component 200 are collectively viewed as a device package 10. The third package component 300 (and external terminals 320, if exist) may be viewed as a package substrate.

In some embodiments, the first package component 100 includes one or more semiconductor die(s) 110 encapsulated by an insulating encapsulation 120. In some embodiments, the semiconductor dies 110 are disposed side-by-side and electrically coupled to one another through the second package component 200. The respective semiconductor die 110 may include a first side 110a facing the second package component 200, a second side 110b opposite to the first side 110a, and a sidewall 110s connected to the first side 110a and the second side 110b. In some embodiments, the semiconductor die 110 includes die connectors 112 (e.g., micro-bumps, metal pillars with or without caps, controlled collapse chip connection (C4) bumps, or the like) distributed at the first side 110a for electrically connecting the second package component 200. The respective semiconductor die 110 may (or may not) include an interconnecting layer 114 for connecting the active/passive devices (not shown) formed on/in the semiconductor substrate 116 to the die connectors 112. The semiconductor substrate 116 may include one or more semiconductor material(s) including, but not limited to, bulk silicon, silicon germanium, group III, group IV, and group V elements, and/or the like. The semiconductor substrate 116 may be a silicon-on-insulator (SOI) substrate, a gradient substrate, a multi-layered substrate, or the like. In some embodiments, the interconnecting layer 114 includes one or more dielectric sublayer(s), metal lines formed in the dielectric sublayers, and conductive vias formed between overlying and underlying metal lines. It is noted that the configuration and the number of the semiconductor dies 110 shown herein is merely for illustrative purposes, and any other configuration and number of the semiconductor dies may be employed depending on product requirements.

With continued reference to FIG. 1A, the respective semiconductor die 110 may have a single function (e.g., a logic die, a processor die (e.g., a central processing unit (CPU) die, a graphics processing unit (GPU) die, an application-specific integrated circuit (ASIC) die, etc.), a memory die (e.g., a dynamic random-access memory (DRAM) die, a static random-access memory (SRAM) die, a stacked memory module, a high-bandwidth memory (HBM) die, etc.), a RF die, a mixed signal die, a I/O die, combinations thereof, and/or the like). The semiconductor dies 110 may be formed in a device wafer (not shown), which includes different die regions that are singulated to form a plurality of semiconductor dies. After the singulation, the semiconductor dies 110 are mounted on the predetermined locations of the second package component 200. In some embodiments, the semiconductor dies 110 have different sizes (e.g., footprint areas) and/or have different functions. In some embodiments, at least one of the semiconductor dies 110 is formed as a die stack having multiple functions (e.g., a system-on-chip or the like). In some embodiments, at least one of the semiconductor dies 110 includes an interface module which bridges the processor module to memory module and translates commands therebetween. Other types of semiconductor dies may be used depending on product requirements.

In some embodiments, the insulating encapsulation 120 extends along sidewalls 110s of the semiconductor dies 110. The insulating encapsulation 120 may be or include molding compound, epoxy resin, molding underfill, and/or the like, and may be applied by compression molding, transfer molding, etc. For example, the insulating encapsulation 120 is formed over the second package component 200 to bury (or cover) the semiconductor dies 110. In some embodiments, the insulating encapsulation 120 is thinned down to expose the second sides 110b of the semiconductor dies 110. The thinning process may be performed by a chemical-mechanical polishing (CMP) process, a grinding process, an etching process, a combination thereof, and/or the like. In some embodiments, after the thinning process, the upper surface 120a of the insulating encapsulation 120 and the second sides 110b of the semiconductor dies 110 are substantially leveled (or coplanar) with one another, within process variations.

With continued reference to FIG. 1A, an underfill layer UF1 may be formed between the gap of the respective semiconductor die 110 and the second package component 200 to laterally cover the electrical connections of the die connectors 116 and the second package component 200. The underfill layer UF1 may be formed in the gap laterally between two of adjacent semiconductor dies 110. As a sufficient amount of the underfill material is dispensed, a portion of the underfill layer UF1 may climb up to partially (or fully) cover the sidewalls 110s of the semiconductor dies 110. The insulating encapsulation 120 may be formed after the formation of the underfill layer UF1, so that the rest portions of the sidewalls 110s that are unmasked by the underfill layer UF1 may be covered by the insulating encapsulation 120. In some embodiments, an upper surface UF1t of the underfill layer UF1 is substantially leveled (or coplanar) with the upper surface 120a of the insulating encapsulation 120 and the second sides 110b of the semiconductor dies 110, within process variations. In alternative embodiments, the upper surface UF1t of the underfill layer UF1 is covered by the insulating encapsulation 120. Alternatively, the underfill layer UF1 is omitted, and the gap between the semiconductor dies 110 and the second package component 200 may be covered by the insulating encapsulation 120 (e.g., the molding underfill).

In some embodiments, a metallic layer 119 is formed on the second sides 110b of the semiconductor dies 110 and may be referred to as a backside metal. The metallic layer 119 may extend across the upper surface 120a of the insulating encapsulation 120. The metallic layer 119 may include Ti, Cu, Ni, Al, Au, Ag, stainless steel, or other suitable metallic materials having relatively high thermal conductivities. In some embodiments, the metallic layer 119 is formed on the first package component 100 prior to a singulation process performed to separate device packages 10 from one another. In other embodiments, the metallic layer 119 is formed after the singulation of the device packages 10. Alternatively, the metallic layer 119 is omitted. Therefore, the metallic layer 119 is illustrated in the dashed lines to indicate it may or may not exist.

With continued reference to FIG. 1A, the second package component 200 may act as an interposer which includes active and/or passive devices or is free of active and/or passive devices. In some embodiments, the second package component 200 includes an interconnect structure 212 on a first side 200a of the second package component 200. The interconnect structure 212 may include one or more dielectric layer(s) and conductive patterns embedded in the dielectric layer(s). In some embodiments, additional interconnect structure (not shown) is formed at a second side 200b opposite to the first side 200a for electrically connecting the semiconductor dies 110. Alternatively, the interconnect structures are respectively formed at the first side 200a and the second side 200b. In some embodiments, the second package component 200 includes conductive terminals 211 distributed at the first side 200a and connecting the interconnect structure 212 to the third package component 300. The conductive terminals 211 may be or include controlled collapse chip connection (C4) bumps, metal pillars, electroless nickel-electroless palladium-immersion gold technique (ENEPIG) formed bumps, solder balls, ball-grid-array (BGA) connectors, and/or the like.

In some embodiments, the interconnect structure 212 is formed on a semiconductor substrate 214. The semiconductor substrate 214 may have a material similar to the material of the semiconductor substrate 116 or may be formed of other suitable material(s). The second package component 200 may include one or more through substrate vias (TSVs) 216 penetrating through the semiconductor substrate 214 to provide vertical and electrical connections between two opposing sides of the semiconductor substrate 214. For example, the TSVs 216 are electrically connected to the conductive patterns of the interconnect structure 212 and extending toward the first package component 100 to be connected to the conductive patterns 218 (e.g., contact pads) at the second side 200b of the second package component 200. The die connectors 112 of the first package component 110 may be in physical and electrical contact with one side of the conductive patterns 218, and the TSVs 216 may be connected to the other side of the conductive patterns 218. The second package component 200 optionally includes a dielectric layer formed on the semiconductor substrate 214 to cover the conductive patterns 218 (e.g., contact pads), and the insulating encapsulation 120 (and the underfill layer UF1, if exists) may be formed on the dielectric layer.

In alternative embodiments, the second package component 200 is formed as a fan-out redistribution structure, where the semiconductor substrate 214 and the TSVs 216 may be omitted or may be replaced with other interconnecting layer(s). In such cases, the first package component and the second package component are collectively viewed as an integrated fan-out package. It is noted that the second package component 200 illustrated herein is merely for illustrative purposes, and additional or fewer element(s) may be arranged in the second package component 200. In some embodiments, the second package component 200 and the first package component 100 are formed in wafer level and then singulated by a singulation process, thereby separating a stack of the first and second package components (100 and 200) into a plurality of device packages 10. After the singulation, the outer sidewall of the first package component 100 is substantially leveled (or coplanar) with the outer sidewall of the second package component 200, within process variations. For example, the device package 10 has coterminous sidewalls including sidewalls of the interconnect structure 212, the semiconductor substrate 214, and the insulating encapsulation 120.

Still referring to FIG. 1A, the third package component 300 includes a first side 300a and a second side 300b opposite to each other. The conductive terminals 211 may be coupled to the first side 300a of the third package component 300. For example, after the singulation, the respective device package 10 is attached to the first side 300a of the third package component 300 by a reflow process or other suitable technique(s). In some embodiments, the underfill layer UF2 is formed in the gap between the second package component 200 and the third package component 300 to surround the conductive terminals 211 for protection. As a sufficient amount of underfill material is dispensed, a portion of the underfill layer UF2 may climb up to partially (or fully) cover the sidewalls of the second package component 200. In some embodiments, the underfill layer UF2 further extends upward to partially (or fully) cover the sidewall of the first package component 100. Alternatively, the underfill layer UF2 is omitted.

In some embodiments, external terminals 320 are formed on the second side 300b of the third package component 300. The device package 10 may be electrically coupled to the external terminals 320 through the third package component 300. The external terminals 320 may land on contact pads 321 of the third package component 300 distributed at the second side 300b. The external terminals 320 may be or include solder balls, ball grid array (BGA), metal pillars, or another suitable connectors, and may be made of conductive materials, such as solder, copper, gold, silver, metal alloy, combinations thereof, or any suitable conductive materials. In some embodiments, the external terminals 320 are configured to be electrically coupled to external systems (not shown) and to transport signals (and/or power) to/from the external systems. The external terminals 320 may be formed prior to the attachment of the support structure 40 (labeled in FIG. 1E) or after the attachment of the support structure 40.

Still referring to FIG. 1A, the third package component 300 may be or include a laminate package substrate, where the conductive patterns are embedded in laminated dielectric layers. In some embodiments, the third package component 300 is a built-up package substrate, which includes a core layer (not shown; e.g., BT resin, FR-4, ceramic, glass, plastic, tape, built-up film, etc.), conductive patterns built on opposite sides of the core layer, and through core vias penetrating through the core layer to connect the conductive patterns at the opposite sides of the core layer. In some embodiments, the package substrate is a multiple-layered circuit board (e.g., a printed circuit board (PCB)) or other types of substrates, depending on product requirements. In some embodiments, the third package component 300 includes trace layers 312 and contact pads 311 formed on the trace layers 312 to be coupled to the conductive terminals 211. The third package component 300 optionally includes a protective layer 305 (e.g., a solder resist layer or the like) partially covering the contact pads 311 to prevent bridging and protect the underlying trace layers 312. The third package component 300 optionally includes optical elements (not individually shown) and/or electrical-optical conversion module for an optical system application. It is noted that the third package component 300 illustrated herein is merely for illustrative purposes, and additional or fewer element(s) may be arranged in the third package component 300.

Still referring to FIG. 1A, one or more fourth package component(s) 105 may be attached to the first side 300a of the third package component 300 and disposed alongside the device package 10. In some embodiments, the respective fourth package component 105 is mounted on the third package component 300 through device connectors 1051 landing on the contact pads 311 of the third package component 300. The respective fourth package component 105 may be or may include integrated passive devices (IPD), integrated voltage regulators (IVR), active components, and/or the like. Other types of the connection between the third and the fourth package components (300 and 105) may be used. The fourth package components 105 may have a different configuration than shown.

Referring to FIG. 1B and with reference to FIG. 1A, an adhesive layer 430 may be formed on the first side 300a of the third package component 300. For example, the adhesive layer 430 is formed as a continuous (or discontinuous) ring along a perimeter around the peripheral region of the protective layer 305. The device packages 10 and the fourth package components 105 may be encircled within a region defined by the adhesive layer 430. In some embodiments, the adhesive layer 430 is dispensed on designated areas of the third package component 300 through a dispensing unit (not shown; e.g., printer, syringe, pump tool, etc.). The material provided with the dispensing unit may be in such as solid, grease, or gel manner. The adhesive layer 430 may be any suitable non-conductive adhesive (e.g., a silicone-based adhesive, an epoxy-resin-based adhesive, an acrylic-based material, etc.), conductive adhesive, attach film, or the like. It is noted that any suitable adhesive material, any suitable method of application, and any suitable thickness may be used for the adhesive layer 430. In some embodiments, after the dispensing process, a curing process is performed to harden the adhesive layer 430. The curing temperature and duration may be dependent on the material chosen for the adhesive layer 430.

Referring to FIG. 1C and with reference to FIG. 1B, a ring portion 431 may be attached to the first side 300a of the third package component 300 through the adhesive layer 430. For example, the ring portion 431 is configured as a stiffener ring for constraining the third package component 300 to minimize warpage (e.g., caused by stress generated during subsequent processing steps) and/or to enhance the robustness of the third package component 300. In some embodiments, the ring portion 431 is placed over the blank area of the third package component 300 and surrounds the device package 10 and the fourth package components 105 (if exist). For example, the ring portion 431 is a single piece and includes one or more hollow region(s) for accommodating the device package 10 and the fourth package components 105 (if exist) therein. In alternative embodiments, the ring portion 431 includes discrete segments arranged around the device package 10 and the fourth package components 105 (if exist). The ring portion 431 may be made of one or more material(s). For example, the ring portion 431 is formed of a rigid material having a CTE similar to that of the underlying third package component 300, thereby reducing CTE mismatch therebetween and reducing stress (and/or deformation) on the third package component 300. The ring portion 431 may counter-balance the forces exerted by the CTE mismatch between the device package 10 and the third package component 300.

The ring portion 431 may be made of a rigid material such as metal(s), metal alloy(s), composites thereof, the like, etc. Examples of the material(s) of the ring portion include copper, aluminum, cobalt, nickel, stainless steel, tungsten, a copper-tungsten alloy, a copper-molybdenum alloy, silver diamond, copper diamond, metal diamond composites, aluminum nitride, aluminum silicon carbide, an iron-nickel alloy (e.g., Alloy42), the like, or combinations thereof. The ring portion 431 may be made of any suitable material which is able to resist warpage and deformation and can be easily processed (e.g., by metalworking, cutting, patterning, etc.) to form the desired shape/pattern. The ring portion 431 may thus provide a rigidifying structure for the resulting package assembly and/or may be formed in any desirable shape and/or may include any desirable pattern for accommodating the components on the third package component 300. The material(s) of the ring portion 431 may (or may not) be thermal conductive, depending on product requirements. In some cases, the thermal conductive property of the ring portion 431 is not required.

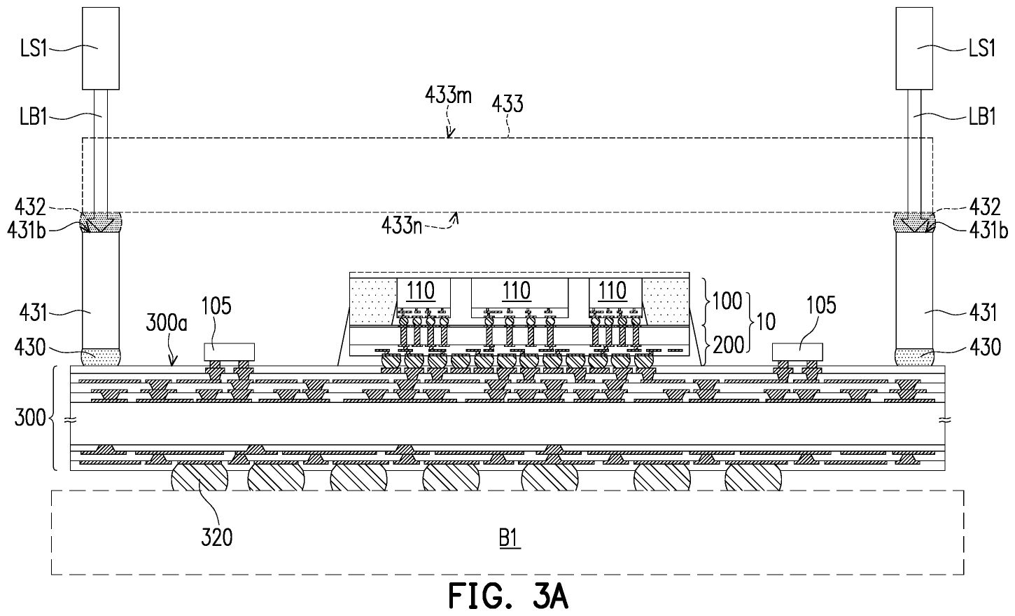

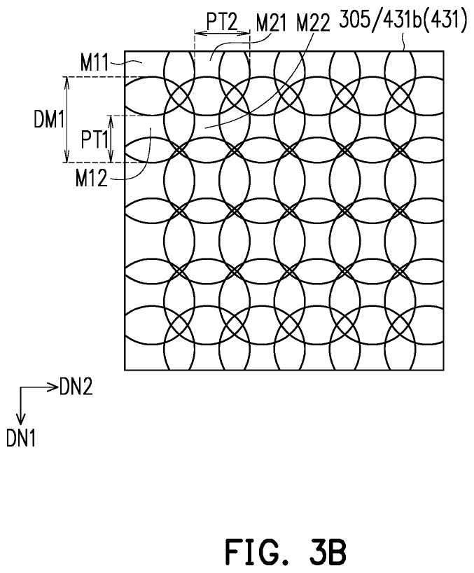

Referring to FIG. 1D and with reference to FIG. 1C, a releasable adhesive layer 432 may be formed on the ring portion 431. For example, the ring portion 431 includes a first side 431a and a second side 431b opposite to each other, where the first side 431a is attached to the third package component 300 through the adhesive layer 430, and the releasable adhesive layer 432 is formed on the second side 431b. The releasable adhesive layer 432 may be de-bonded in the subsequent process as discussed in more detail in accompanying with FIG. 3A. The candidate material(s) of the releasable adhesive layer 432 may include a polymeric-based material or any suitable material depending on the subsequently-performed de-bonding process. For example, the releasable adhesive layer 432 includes a laser-release (and/or thermal-release) material which may lose its adhesive property when exposed to certain wavelength(s) of a radiation (and/or heated). In some embodiments, the wavelengths range from the ultraviolet to the infrared (or near infrared). The releasable adhesive layer 432 may respond to radiation (e.g., from a laser beam or other light source), which leads to decomposition of the releasable adhesive layer 432, causing bonding integrity to be lost and allowing the lid portion to be released from the ring portion 431 without applying chemicals/mechanical force.

In some embodiments, the material of the releasable adhesive layer 432 is different from the material of the adhesive layer 430. For example, as compared to the material(s) of the adhesive layer 430, the releasable adhesive layer 432 further includes additive(s) or substance(s) which have certain laser (or thermal) absorbance, so that the releasable adhesive layer 432 may be disintegrated by radiation (or heat) during the de-bonding process as discussed in FIG. 3A. In some embodiments, the releasable adhesive layer 432 is formed by dispensing a suitable adhesive material on the second side 431b of the ring portion 431 through a dispensing unit (not shown; e.g., printer, syringe, pump tool, etc.). The material provided with the dispensing unit may be in such as solid, grease, or gel manner. It is noted that any suitable adhesive material, any suitable method of application, and any suitable thickness may be used for the releasable adhesive layer 432 and may depend on the de-bonding process requirements.

Referring to FIG. 1E and with reference to FIG. 1D, a lid portion 433 may be attached to the ring portion 431 through the releasable adhesive layer 432. The releasable adhesive layer 432 may temporarily fix the lid portion 433 to the ring portion 431. The attachment of the lid portion 433 may entail hardening the releasable adhesive layer 432 in the presence and/or absence of a compressive force and/or suitable mechanical pressure, whether by applying heat and/or by other means. In some embodiments, the lid portion 433 is pressed toward the releasable adhesive layer 432 through clamping or other suitable means. In some embodiments, during the attachment of the lid portion 433, a thermal treatment process (e.g., curing or the like) is performed on the releasable adhesive layer 432. For example, during applying the force to the lid portion 433, the releasable adhesive layer 432 is cured and solidified. The curing temperature and duration may be dependent on the material chosen for the releasable adhesive layer 432.

The lid portion 433, the releasable adhesive layer 432, the ring portion 431, and the adhesive layer 430 may be collectively viewed as a support structure 40. The lid portion 433 of the support structure 40 may provide a cover for the underlying structure including the device package 10, the fourth package components 105 (if exist), and the third package component 300. The lid portion 433 may protect the underlying structure from the damage that may be resulted in the subsequent processing. As compared to the lid portion 433, the ring portion 431 of the support structure 40 may feature material properties which mainly contribute to provide rigidity (or stiffness) to reduce warpage and prevent breakage that may occur during the subsequently on-board process (described in FIG. 3A). In some embodiments, the material of the lid portion 433 is different from the ring portion 431. For example, the ring portion 431 is more rigid than the lid portion 433. In some cases, the thermal conductive property of the lid portion 433 is not required, and the lid portion 433 may not be thermal conductive.

The lid 520 may be a single piece or may include more than one piece that may be of the same or different materials. The lid portion 433 may be made of one or more material(s) transparent to the radiation used in the subsequently-performed de-bonding process, while the ring portion 431 may be opaque to the radiation used in the de-bonding process. The material(s) of the lid portion 433 may include glass, polymeric-based material, or any suitable material depending on the requirements of the subsequently-performed de-bonding process. The lid portion 433 may be a suitable composite structure that is transparent to at least a specified wavelength of the radiation used during the de-bonding process as described in FIG. 3A. The material(s) of the lid portion 433 may be tailored for the subsequently-performed de-bonding process in order to meet the various de-bonding process requirements of customers. For example, the CTE of the lid portion 433 is greater than 0 ppm/° C. and may be less than or substantially equal to 13 ppm/° C. The Young's modulus of the lid portion 433 may be in a range of about 60 GPa and 150 GPa. The thickness 433T of the lid portion 433 may be in a range of about 0.3 mm and about 5.0 mm. The CTE, the Young's modulus, and the thickness 433T may be customized depending on the requirements of the de-bonding process.

With continued reference to FIG. 1E, the support structure 40 attached to the third package component 300 may form a cavity (or a sealed region) in which the device package 10 and the fourth package components 105 (if exist) are housed. The lid portion 433 may be spatially spaced apart from the device package 10 in a stacking direction of the device package 10 and the third package component 300 by a non-zero distance D1. For example, the non-zero distance D1 is a vertical distance measured along the stacking direction of the device package 10 and the third package component 300 or measured between the inner surface 433n of the lid portion 433 and the top surface 10t of the device package 10. The top surface 10t of the device package 10 may include the upper surface 120a of the insulating encapsulation 120, the second sides 110b of the semiconductor dies 110, and the upper surface UF1t of the underfill layer UF1 (if any) which are labeled in FIG. 1A. In some embodiments where the metallic layer 119 is present, the non-zero distance D1 is measured between the inner surface 433n of the lid portion 433 and the top surface of the metallic layer 119. In some embodiments, a first gap G1 is formed vertically between the lid portion 433 and the device package 10, a second gap G2 is formed laterally between the ring portion 431 and the device package 10, and the first gap G1 is in spatial communication with the second gap G2. The first gap G1 and the second gap G2 may be air gaps (or gas-filled gaps, if necessary).

In some embodiments, the maximum lateral dimension 433W (e.g., a width or a length) of the lid portion 433 is less than (or substantially equal to) the maximum lateral dimension 300W of the third package component 300. For example, an orthographic projection of the boundary of the lid portion 433 overlaps and/or is located within an orthographic projection of the boundary of the third package component 300. In some embodiments, the sidewall 433s of the lid portion 433 is substantially aligned (or coplanar) with the sidewall 431s of the ring portion 431. For example, an orthographic projection of the boundary of the ring portion 431 overlaps and/or is located within an orthographic projection of the boundary of the third package component 300. In alternative embodiments, the sidewall 433s of the lid portion 433 is laterally offset from the sidewall 431s of the ring portion 431 and/or the sidewall 300s of the third package component 300. It should be noted that the lid portion 433 may come in a variety of shapes and sizes as feasibly permitted depending on product requirements.

The structure in FIG. 1E may be viewed as a package assembly PS1. The support structure 40 of the package assembly PS1 may include the ring portion 431 which provides rigidity to the third package component 300 and helps reduce warpage of the package assembly PS1. This may facilitate the subsequently-performed on-board process as will be described in accompanying with FIG. 3A. The support structure 40 may include the lid portion 433 and the releasable adhesive layer 432 coupling the lid portion 433 to the ring portion 431. The materials of the lid portion 433 and the releasable adhesive layer 432 may be customized based on the requirements of warpage adjustment and the subsequently-performed de-bonding process (see FIG. 3A). This may increase flexibility of the candidate material selection. The lid portion 433 may be separated from the device package 10 without any physical connection formed therebetween. There is no TIM formed between the lid portion 433 and the device package 10, so that delamination/crack issues associated with the TIM are eliminated and the subsequent removal process of the TIM is omitted. The lid portion 433 may be temporarily adhered to the ring portion 431 through the releasable adhesive layer 432 instead of using fixing components (e.g., a screw). In this manner, local deformations caused by the screwing process may be eliminated, and an unscrewing process may be replaced with a more efficient radiation de-bonding process to increase throughput and reduce processing cost.

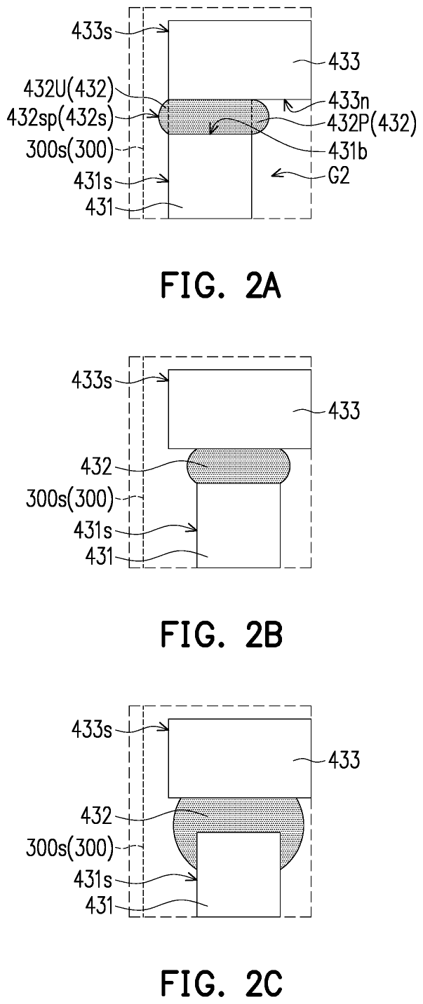

FIGS. 2A-2C are schematic cross-sectional views showing the variations of the structure in the dashed box A of FIG. 1E, in accordance with some embodiments. Depending on the amount of the releasable adhesive layer 432 and the position relationship between the lid portion 433 and the ring portion 431, variations will be described, and the variations are applicable to other embodiments described in the present disclosure. Referring to FIG. 2A and with reference to FIG. 1E, outer edges of the lid portion 433 and the ring portion 431 may be substantially aligned, and the sufficient amount of the releasable adhesive layer 432 is applied to attach the lid portion 433 to the ring portion 431. For example, the releasable adhesive layer 432 may be attached to the inner surface 433n of the lid portion 433 and the second side 431b of the ring portion 431. The sidewall 433s of the lid portion 433 and the sidewall 431s of the ring portion 431 may be exposed by the releasable adhesive layer 432. The releasable adhesive layer 432 may be laterally protruded from the inner surface 433n of the lid portion 433 and the second side 431b of the ring portion 431. In some embodiments, the outermost point 432sp of the outer surface 432s of the releasable adhesive layer 432 is beyond the sidewall 433s of the lid portion 433 and the sidewall 431s of the ring portion 431, but is not beyond the virtual plane on which the sidewall 300s of the third package component 300 is disposed. The lid portion 433, the releasable adhesive layer 432, and the ring portion 431 may be disposed within the boundary of the third package component 300 defined by the sidewall 300s in the top view (not shown). In some embodiments, the releasable adhesive layer 432 includes an outer protrusion 432U and an inner protrusion 432P, where the outer protrusion 432U is beyond the sidewall 433s of the lid portion 433 and the sidewall 431s of the ring portion 431, and the inner protrusion 432P extends laterally toward the second gap G2. The amount of the inner protrusion 432P may be greater than (or substantially equal to) the amount of the outer protrusion 432U.

Referring to FIG. 2B and with reference to FIG. 2A, outer edges of the lid portion 433 and the ring portion 431 are laterally offset from each other, and the sufficient amount of the releasable adhesive layer 432 is applied to attach the lid portion 433 to the ring portion 431. For example, the structure shown in FIG. 2B is similar to the FIG. 2A, except that the sidewall 433s of the lid portion 433 is laterally offset (or protruded) from the sidewall 431s of the ring portion 431 but is not beyond the virtual plane on which the sidewall 300s of the third package component 300 is disposed. The sidewall 433s of the lid portion 433 may be between the sidewall 300s of the third package component 300 and the sidewall 431s of the ring portion 431 in the top view (not shown). Referring to FIG. 2C and with reference to FIG. 2B, the structure shown in FIG. 2C is similar to the FIG. 2B, except that the large amount of the releasable adhesive layer 432 is applied to attach the lid portion 433 to the ring portion 431. For example, the releasable adhesive layer 432 extends to cover the sidewall 431s of the ring portion 431. The top of the ring portion 431 may be embedded in the releasable adhesive layer 432.

FIG. 3A is a schematic cross-sectional view showing that a de-bonding process is performed on the package assembly PS1 of FIG. 1E, and FIG. 3B is a schematic and partial top-down view showing de-bonded marks, in accordance with some embodiments. Referring to FIG. 3A and with reference to FIG. 1E, the package assembly PS1 is optionally mounted on a circuit board B1. The circuit board B1 may be or include a printed circuit board, a mother board, a system board, another package component, the like, a combination thereof, etc. In some embodiments, the package assembly PS1 is placed over the circuit board B1, and a reflow process is performed on the external terminals 320 in order to couple the overlying structure to the circuit board B1. An underfill layer (not shown) is optionally formed in the gap between the package assembly PS1 and the circuit board B1 to surround the reflowed external terminals 320 for protection. Alternatively, the package assembly PS1 is not coupled to the circuit board B1 according to product design. Accordingly, the circuit board B1 is illustrated in the dashed lines to indicate it may (or may not) exist.

In some embodiments, a de-bonding process is performed on the support structure 40 of the package assembly PS1 to reveal the components (e.g., the device package 10 and the fourth package components 105 (if exist)) that are housed in the seal region defined by the support structure 40 and the third package component 300. In some embodiments where the package assembly PS1 is coupled to the circuit board B1, the de-bonding process is performed after coupling the package assembly PS1 to the circuit board B1. In some embodiments, after the de-bonding process, one or more heat-dissipating component(s) may be mounted onto the device package 10 and the ring portion 431 depending on the product requirements. In some embodiments where the package assembly PS1 is a part of an optical system and is not coupled to the circuit board B1, the de-bonding process is performed before an optical source (e.g., fibers; not shown) are coupled to the package assembly PS1.

With continued reference to FIG. 3A and FIG. 1E, during the de-bonding process, the releasable adhesive layer 432 may be exposed to an energy source LS1 (e.g., an ultraviolet laser, a carbon dioxide laser, an infrared laser, etc.) so as to facilitate separation of the lid portion 433 and the ring portion 431. For example, the de-bonding process is performed using radiation, which penetrates through the lid portion 433 and removes (or burns) all or part of the releasable adhesive layer 432. The ring portion 431 may have the function of preventing the radiation from reaching the underlying structure. In some embodiments, the lid portion 433 is released from the ring portion 431 by using a laser de-bonding process. For example, during the laser de-bonding process, the energy source LS1 disposed over the upper surface 433m of the lid portion 433 is configured to generate a pulsed laser for irradiating the releasable adhesive layer 432. In some embodiments, the laser beam LB1 emitted from the energy source LS1 is used to irradiate the releasable adhesive layer 432 with a series of laser beam pulses.

Referring to FIG. 3B and with reference to FIG. 3A, during the laser de-bonding process, the energy source LS1 (e.g., a laser source of a de-bonding tool or the like) may be scanned across the second side 431b of the ring portion 431 to remove (or decompose) the releasable adhesive layer 432 formed thereon. In some embodiments, a series of laser beam pulses is used to form overlapping marks on the ring portion 431. For example, each one of the series of laser beam pulses may form a de-bonded mark (e.g., laser beam pulse exposure) on the second side 431b of the ring portion 431. The de-bonded marks (e.g., M11, M12, M21, and M22) are represented in FIG. 3B by the circles, but the de-bonded marks may have other shapes (e.g., an elliptical shape, a rectangular shape, a square shape, an irregular shape, etc.) depending on the recipe of the laser de-bonding process. In some embodiments, during the laser de-bonding process, a first portion of the releasable adhesive layer 432 that is desired to be removed may be irradiated with a first one of the laser beam pulses (not shown). During the first one of the laser beam pulses, the first portion of the releasable adhesive layer 432 may be removed (or decompose) to form the de-bonded mark M11 on the second side 431b of the ring portion 431.

In some embodiments, once the de-bonded mark M11 has been formed, the laser beam is moved along the first direction DN1 to irradiate a second portion of the releasable adhesive layer 432 with a second one of the laser beam pulses. The second one of the laser beam pulses may be similar to the first one of the laser beam pulses. During the second one of the laser beam pulses, the second portion of the releasable adhesive layer 432 may be removed to form the de-bonded mark M12 on the second side 431b of the ring portion 431, where the de-bonded mark M12 overlaps the de-bonded mark M11 in the first direction DN1. In some embodiments, the de-bonded mark M12 is offset from the de-bonded mark M11 by a first pitch PT1 measured along the first direction DN1. For example, the first pitch PT1 is greater than zero and less than the diameter DM1 of the de-bonded mark (M11 or M12). This process of using offset laser beam pulses to form overlapping but offset de-bonded marks to remove the releasable adhesive layer 432 may be continued to form the first line including the de-bonded marks (M11, M12 . . . ), where the length of the first line is substantially equal to (or greater than) the length of the second side 431b of the ring portion 431.

In some embodiments, once the first line is finished, the laser beam is moved along the second direction DN2 to irradiate a third portion of the releasable adhesive layer 432 with a third one of the laser beam pulses, where the second direction DN2 is substantially perpendicular to the first direction DN1. During the third one of the laser beam pulses, the third portion of the releasable adhesive layer 432 may be removed to form the de-bonded mark M21 on the second side 431b of the ring portion 431, where the de-bonded mark M21 overlaps the de-bonded mark M11 in the second direction DN2. For example, the de-bonded mark M21 is offset from the de-bonded mark M11 by a second pitch PT2 measured along the second direction DN2, where the second pitch PT2 is greater than zero and less than the diameter DM1 of the de-bonded mark (M11 or M21). The de-bonded mark 21 may also overlap the de-bonded mark 12. In some embodiments, once the de-bonded mark M21 has been formed, the laser beam may be moved along the first direction DN1 to irradiate a fourth portion of the releasable adhesive layer 432 with a fourth one of the laser beam pulses, where the fourth one of the laser beam pulses may be similar to the third one of the laser beam pulses. During the fourth one of the laser beam pulses, the fourth portion of the releasable adhesive layer 432 may be removed to form the de-bonded mark M22 on the second side 431b of the ring portion 431, where the de-bonded mark M22 may overlap the de-bonded marks (M11, M12, and M21).

By overlapping the de-bonded marks, there will be portions of the de-bonded marks that have been irradiated by multiple ones of the laser beam pulses, with each exposure removing additional material from the releasable adhesive layer 432 and causing different kerf depths. For example, the individual de-bonded mark may have different depths within the boundary of the de-bonded mark, where the overlapped region of the de-bonded mark has a deeper depth than the non-overlapped region of the de-bonded mark. Other shapes, dimensions, or offsets are possible, and the de-bonded marks may have a different number or arrangement than shown. The de-bonding process may be automatically performed. For example, the laser de-bonding tool includes the controller (not shown) which is programmable to control the moving path(s) of the laser beam. In this manner, the process time of the de-bonding process may be shortened.

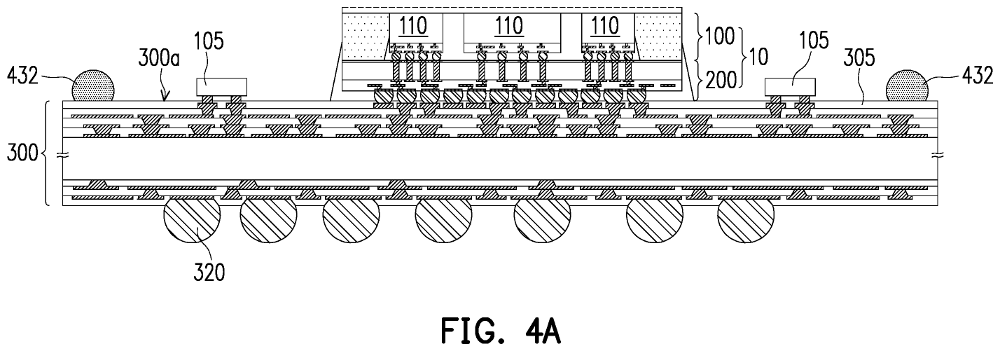

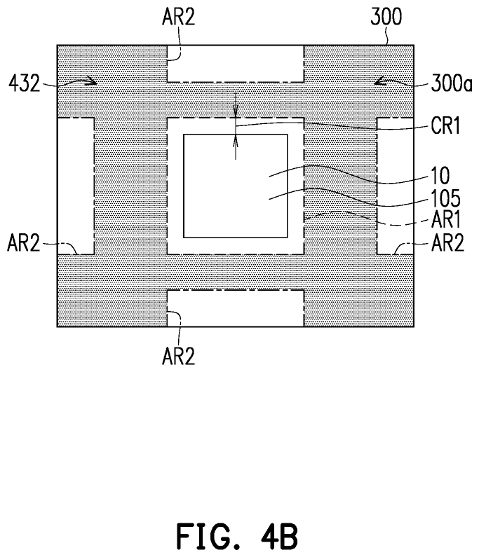

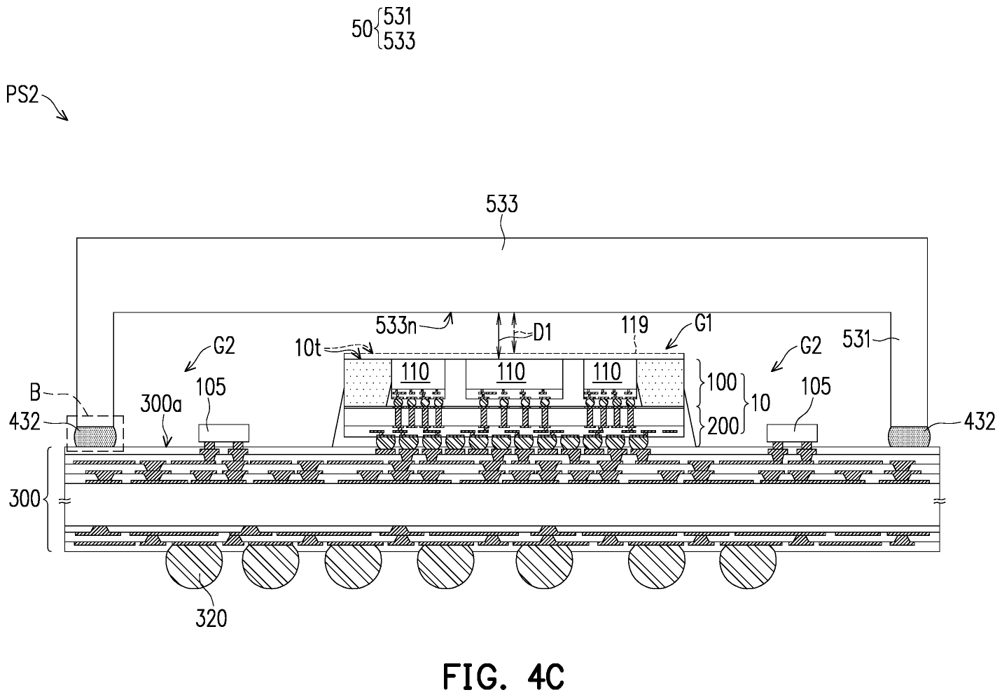

FIGS. 4A and 4C are schematic cross-sectional views of various stages of manufacturing a package assembly, and FIG. 4B is a schematic top-down view showing a possible distribution area of the release adhesive layer on the third package component, in accordance with some embodiments. Unless explicitly stated otherwise, the materials and the formation methods of the components in these embodiments are essentially the same as the like components, which are denoted by like reference numerals in the embodiments described in accompanying with FIGS. 1A-1E.

Referring to FIGS. 4A-4B and with reference to FIG. 1B and FIG. 1E, the structure shown in FIG. 4A is similar to the structure shown in FIG. 1B, except that the adhesive layer 430 formed on the third package component 300 is replaced with the releasable adhesive layer 432. The possible dispensing area of the release adhesive layer 432 is illustrated in the top-down view of FIG. 4B. The release adhesive layer 432 may be formed across the first side 300a of the third package component 300 except for the pre-defined areas. It should be noted that the top-down view of FIG. 4B is merely an illustrative example, and release adhesive layer 432 may spread across the first side 300a of the third package component 300 except for the pre-defined areas or may be formed as discrete segments without covering the pre-defined areas. The pre-defined areas may include a first area AR1 within which the device package 10 (and the fourth package components 105, if exists) are located, and one or more second area(s) AR2 reserved for subsequent connections (e.g., optical connections and/or electrical connections, etc.). In the top-down view, the boundary of the device package 10 (and the boundaries of the fourth package components 105, if exists) may be located within the first area AR1, and a non-zero clearance CR1 may be between the boundary of the first area AR1 and the boundary of the device package 10 (and the boundaries of the fourth package components 105, if exists). For example, the non-zero clearance CR1 is at least 1 mm, but the non-zero clearance CR1 may have other value depending on product design.

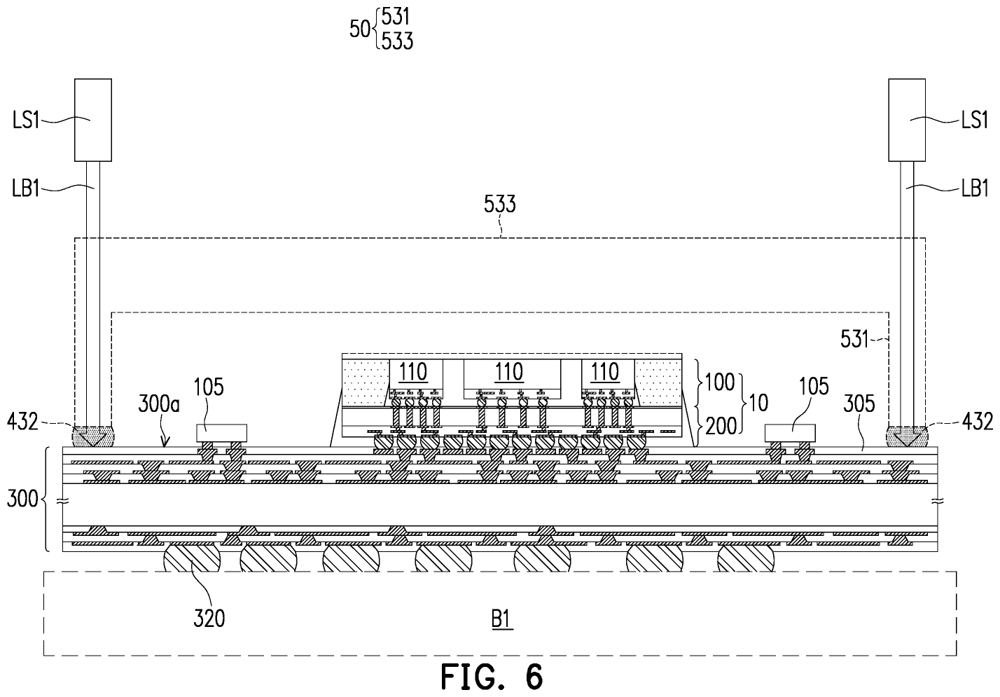

Referring to FIG. 4C and with reference to FIG. 4A and FIG. 1E, once the releasable adhesive layer 432 is formed on the first side 300a of the third package component 300, a support structure 50 may be attached to the first side 300a of the third package component 300 by the releasable adhesive layer 432. The structure illustrated in FIG. 4C may be viewed as a package assembly PS2. The support structure 50 may be similar to the support structure 40 described in FIG. 1E. For example, the support structure 50 includes a ring portion 533 attached to the releasable adhesive layer 432 and a lid portion 533 overlying the ring portion 533. The support structure 50 may be a single-piece component, the ring portion 533 and the lid portion 533 may be integratedly formed, and thus no visible interface is formed therebetween. The ring portion 533 and the lid portion 533 may be formed of the same material (or similar materials). In some embodiments, the ring portion 533 and the lid portion 533 are made of one or more material(s) transparent to the radiation used in the subsequently-performed de-bonding process. The material(s) of the ring portion 533 and the lid portion 533 may be similar to the material(s) of the lid portion 433 described in FIG. 1E, and thus the details thereof are not repeated herein. The materials of the support structure 50 and the releasable adhesive layer 432 may be customized based on the requirements of warpage adjustment and the subsequently-performed de-bonding process (see FIG. 6). This may increase flexibility of the candidate material selection.

The support structure 50 attached to the third package component 300 may form a sealed region (or a cavity) in which the device package 10 and the fourth package components 105 (if exist) are housed. For example, the support structure 50 is spatially separated from the device package 10 without any physical connection formed therebetween. The lid portion 533 may be spaced apart from the device package 10 in the stacking direction of the device package 10 and the third package component 300 by the non-zero distance D1 measured between the inner surface 533n of the lid portion 533 and the top surface 10t of the device package 10. In some embodiments where the metallic layer 119 is present, the non-zero distance D1 is measured between the inner surface 433n of the lid portion 433 and the top surface of the metallic layer 119. In some embodiments, the first gap G1 is formed vertically between the lid portion 533 and the device package 10, the second gap G2 is formed laterally between the ring portion 531 and the device package 10. The first gap G1 may be in spatial communication with the second gap G2.

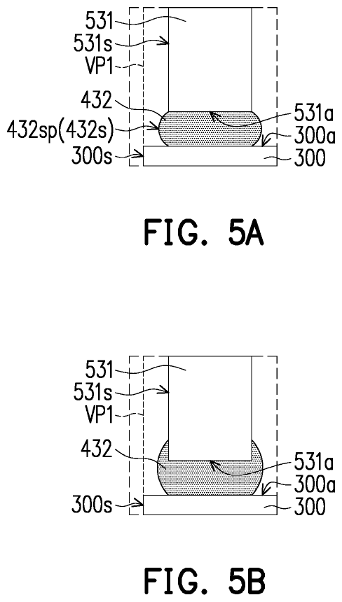

FIGS. 5A and 5B are schematic cross-sectional views showing the variations of the structure in the dashed box B of FIG. 4C, in accordance with some embodiments. Referring to FIG. 5A and with reference to FIG. 4C, the releasable adhesive layer 432 may be attached to the first side 531a of the ring portion 531 and the first side 300a of the third package component 300, and the sidewall 531s of the ring portion 531 may be exposed by the releasable adhesive layer 432. The releasable adhesive layer 432 may be laterally protruded from the first side 531a of the ring portion 531. In some embodiments, the outermost point 432sp of the outer surface 432s of the releasable adhesive layer 432 is beyond the sidewall 531s of the ring portion 531, but is not beyond the virtual plane VP1 on which the sidewall 300s of the third package component 300 is disposed. The releasable adhesive layer 432 and the ring portion 531 may be disposed within the boundary of the third package component 300 defined by the sidewall 300s in the top view (not shown). Referring to FIG. 5B and with reference to FIG. 5A, the structure shown in FIG. 5B is similar to the FIG. 5A, except that the releasable adhesive layer 432 may extend to cover the sidewall 531s of the ring portion 531. For example, the bottom of the ring portion 531 is embedded in (or inserted into) the releasable adhesive layer 432.

FIG. 6 is a schematic cross-sectional view showing that a de-bonding process is performed on the package assembly of FIG. 4C, in accordance with some embodiments. The structure shown in FIG. 6 is similar to the structure shown in FIG. 3A, and like reference numbers are used to designate like elements. Referring to FIG. 6 and with reference to FIG. 4C and FIGS. 3A-3B, the package assembly PS1 is optionally mounted on the circuit board B1 as described in FIG. 3A. In some embodiments, a de-bonding process is performed on the support structure 50 to reveal the components (e.g., the device package 10 and the fourth package components 105 (if exist)) that are housed in the seal region defined by the support structure 50 and the third package component 300. During the de-bonding process, the energy source LS1 may be used to irradiate the releasable adhesive layer 432 until the releasable adhesive layer 432 loses its adhesive property, thereby facilitating separation of the support structure 50.

The de-bonding process performed on the support structure 50 may be similar to the de-bonding process performed on the lid portion 433 described in FIG. 3A, except that the radiation (e.g., the laser beam LB1) passing through both of the lid portion 533 and the ring portion 531 and removing (or burning) all or part of the releasable adhesive layer 432 on the third package component 300. During the de-bonding process, the energy source LS1 may be scanned across the first side 300a of the third package component 300 to remove (or decompose) the releasable adhesive layer 432 formed thereon. In some embodiments, a series of laser beam pulses is used to form overlapping marks on the first side 300a of the third package component 300 (e.g., the protective layer 305). The de-bonded marks formed on the first side 300a of the third package component 300 may be similar to the de-bonded marks described in FIG. 3B, and thus the details thereof are not repeated herein.

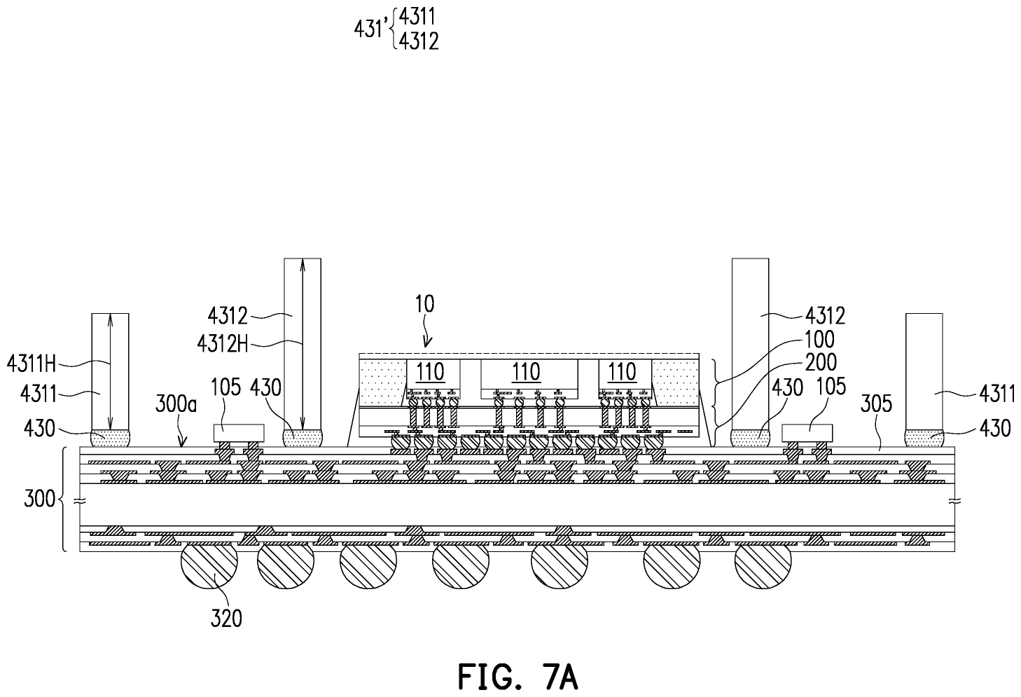

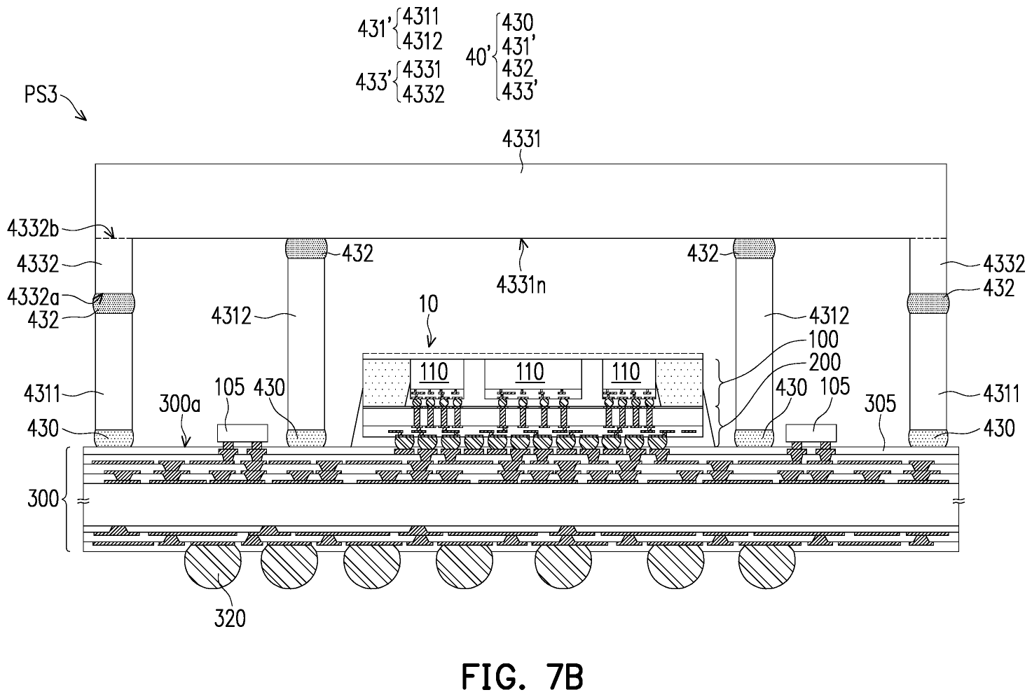

FIGS. 7A-7B are schematic cross-sectional views of various stages of manufacturing a package assembly, in accordance with some embodiments. Unless explicitly stated otherwise, the materials and the formation methods of the components in these embodiments are essentially the same as the like components, which are denoted by like reference numerals in the embodiments described in accompanying with FIGS. 1A-1E.

Referring to FIG. 7A and with reference to FIG. 1C, the structure shown in FIG. 7A is similar to the structure shown in FIG. 1C, except for the configuration of the adhesive layer 430 and the configuration of the ring portions 431′. For example, the adhesive layer 430 includes a portion formed on the periphery of the first side 300a of the third package component 300 and another portion formed on the region of the first side 300a between the device package 10 and the respective fourth package component 105. The ring portion 431′ may be disposed on the adhesive layer 430 and attached to the third package component 300 through the adhesive layer 430. The ring portion 431′ is similar to the ring portion 431 described in FIG. 1C, except that the ring portion 431′ includes a first portion 4311 connected to the portion of the adhesive layer 430 dispensed on the periphery of the first side 300a of the third package component 300 and a second portion 4312 connected to another portion of the adhesive layer between the device package 10 and the respective fourth package component 105. The height 4311H of the first portion 4311 may be less than the height 4312H of the second portion 4312. In some embodiments, the height 4311H of the first portion 4311 is less than the overall height of the respective fourth package components 105. In such cases, the height 4311H may be in a range of about 0.3 mm and about 0.5 mm. In alternative embodiments, the heights (4311H and 4312H) are substantially equal to each other.

Referring to FIG. 7B and with reference to FIG. 7A and FIGS. 1D-1E, the releasable adhesive layer 432 may be formed on the first portion 4311 and the second portion 4312 of the ring portion 431′. The material and the forming method of the releasable adhesive layer 432 may be similar to those of the releasable adhesive layer 432 described in FIG. 1D, and thus the details thereof are not repeated herein. Once the releasable adhesive layer 432 is formed on the ring portion 431′, the lid portion 433′ may be attached to the ring portion 431′ through the releasable adhesive layer 432. The lid portion 433′, the releasable adhesive layer 432, the ring portion 431′, and the adhesive layer 430 may be collectively viewed as a support structure 40′. The structure shown in FIG. 7B may be viewed as a package assembly PS3. For example, an optical source and/or optical elements may be coupled to the package assembly PS3 to form an optical system.

The material and the attachment of the lid portion 433′ may be similar to those of the lid portion 433 described in FIG. 1E, and thus the details thereof are not repeated herein. The lid portion 433′ includes a main portion 4331 and an extension 4332 connected to the main portion 4311. The second portion 4312 of the ring portion 431′ may be attached to the inner surface 4331n of the main portion 4311 through the releasable adhesive layer 432, and the first portion 4311 of ring portion 431′ may be attached to the extension 4332 through the releasable adhesive layer 432. The main portion 4331 may be similar to the lid portion 433, and the extension 4332 extends downward from the inner surface 4331n of the main portion 4311. The extension 4332 may be disposed at the periphery of the main portion 4311. For example, the extension 4332 includes a first end 4332a connected to the releasable adhesive layer 432 and a second end 4332b attached to the main portion 4311. In some embodiments, the main portion 4311 and the extension 4332 are integratedly formed. In some other embodiments, the main portion 4311 and the extension 4332 are made of different materials, but both of the materials of the main portion 4311 and the extension 4332 are transparent to the radiation used in the subsequently-performed de-bonding process. In certain embodiments where the heights of the first and second portions (4311 and 4312) are substantially equal, the extension 4332 may be omitted.

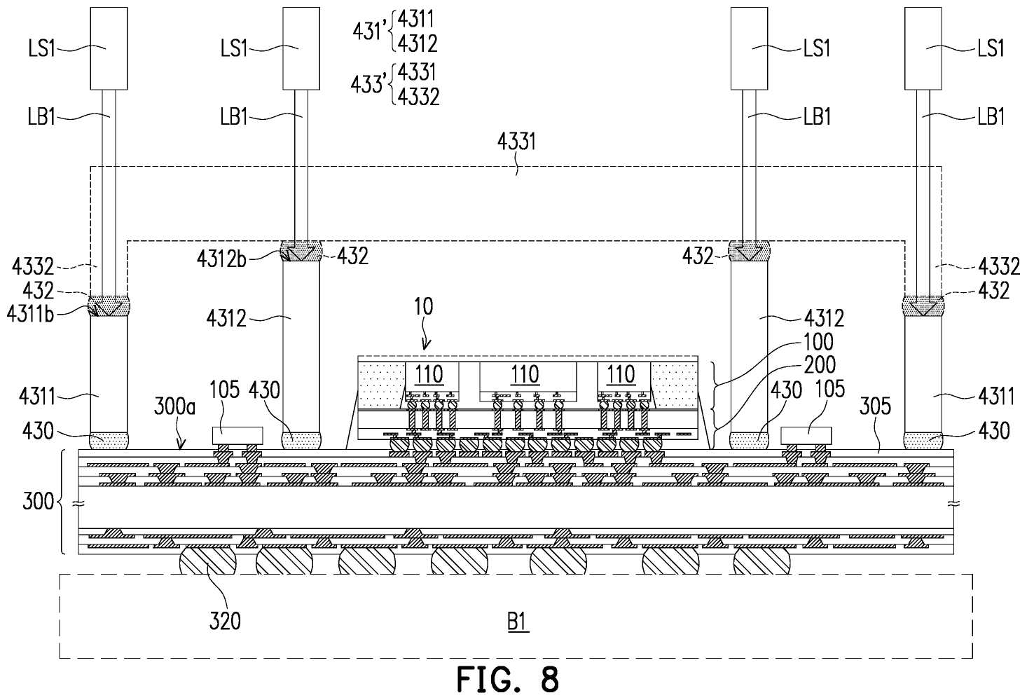

FIG. 8 is a schematic cross-sectional view showing that a de-bonding process is performed on the package assembly of FIG. 7B, in accordance with some embodiments. The structure shown in FIG. 8 is similar to the structure shown in FIG. 3A, and like reference numbers are used to designate like elements. Referring to FIG. 8 and with reference to FIG. 7B and FIGS. 3A-3B, the package assembly PS3 is optionally mounted on the circuit board B1 as described in FIG. 3A. In some embodiments, a de-bonding process is performed on the support structure 40′ to reveal the components (e.g., the device package 10 and the fourth package components 105 (if exist)) that are housed in the seal region defined by the support structure 40′ and the third package component 300. During the de-bonding process, the energy source LS1 may be used to irradiate each portion of the releasable adhesive layer 432 until the releasable adhesive layer 432 loses its adhesive property, such that the lid portion 433′ may be disconnected to the ring portion 431′. The de-bonding process performed on the support structure 40′ may be similar to the de-bonding process performed on the support structure 40 described in FIG. 3A, and thus the details thereof are not repeated herein. After the de-bonding process, the de-bonded marks may be formed on the second side 4311b of the first portion 4311 and the second side 4312b of the second portion 4312. The de-bonded marks may be similar to the de-bonded marks described in FIG. 3B, and thus the details thereof are not repeated herein.

Embodiments may have one or a combination of the following features and/or advantages. By attaching the support structure on the third package component to accommodate the device package and the fourth package components (if exist) in the cavity, the coplanarity of the package assembly may be improved. The support structure may include separate pieces or may be a single-piece component, depending on product requirements. In some embodiments where the support structure includes separate pieces, the lid portion and the ring portion are attached through the releasable adhesive layer instead of using fixing components (e.g., a screw or the like). In this manner, by removing the releasable adhesive layer, the device package and the fourth package components (if exist) that were housed in the cavity may be revealed. Since the unscrewing process is replaced with the de-bonding process of the releasable adhesive layer, the process time of de-bonding may be shortened.

The materials of the support structure and the releasable adhesive layer may be customized based on the requirements of warpage adjustment and the de-bonding process. This may increase flexibility of the candidate material selection of the support structure. In some embodiments where the radiation de-bonding process is performed on the package assembly to release the support structure, the support structure is transparent to the radiation used in the de-bonding process, so that the releasable adhesive layer may be irradiated by the radiation and then removed. The support structure may be separated from the device package without any physical connection formed therebetween. For example, there is no TIM formed between the support structure and the device package, so that the issues associated with the TIM are eliminated and the subsequent removal process of the TIM may be omitted.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In accordance with some embodiments, a package assembly includes a device package including an encapsulated die and an interposer disposed below the encapsulated die, a package substrate disposed below the device package and electrically coupled to the encapsulated die through the interposer, and a support structure disposed on the package substrate. The device package is housed in a cavity formed by the support structure and the support structure. The support structure includes a lid portion made of a material transparent to a radiation, a ring portion between the lid portion and the package substrate, and a releasable adhesive layer being response to the radiation.

In accordance with some embodiments, a package assembly includes a package substrate, a device package disposed on a side of the package substrate and electrically coupled to the package substrate, and a support structure coupled to the side of the package substrate to accommodate the device package therein. The support structure includes a lid portion including a transparent material and a ring portion vertically between the lid portion and the package substrate. A first space is between the lid portion and the device package, and a second space is between the ring portion and the device package and is in spatial communication with the first space.

In accordance with some embodiments, a manufacturing method of a package assembly includes: coupling a device package to a side of a package substrate; and coupling a support structure to the side of the package substrate to accommodate the device package therein. The support structure includes a lid portion made of a material transparent to a radiation, a ring portion between the lid portion and the package substrate, and a releasable adhesive layer being response to the radiation.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package assembly, comprising:
a device package comprising an encapsulated die and an interposer disposed below the encapsulated die;
a package substrate disposed below the device package and electrically coupled to the encapsulated die through the interposer; and
a support structure disposed on the package substrate, the device package being housed in a cavity formed by the support structure and the support structure, and the support structure comprising:
a lid portion made of a material transparent to a radiation;
a ring portion between the lid portion and the package substrate; and
a releasable adhesive layer being response to the radiation.

2. The package assembly of claim 1, wherein a first gap is vertically between an inner surface of the lid portion and a top surface of the device package facing the inner surface of the lid portion.

3. The package assembly of claim 2, wherein a second gap is laterally between an inner sidewall of the ring portion and a sidewall of the device package, and the first gap is in spatial communication with the second gap.

4. The package assembly of claim 2, wherein the first gap is an air gap.

5. The package assembly of claim 1, wherein the lid portion is attached to the ring portion through the releasable adhesive layer.

6. The package assembly of claim 1, wherein the support structure further comprises an adhesive layer coupling the ring portion to the package substrate, and the adhesive layer comprises a material different from the releasable adhesive layer.

7. The package assembly of claim 1, wherein the ring portion is made of a material opaque to the radiation.

8. The package assembly of claim 1, wherein the ring portion comprises a first portion disposed over a periphery of the package substrate and a second portion disposed laterally between the device package and the first portion.

9. The package assembly of claim 1, wherein an end of the ring portion facing the lid portion is inserted into the releasable adhesive layer.

10. The package assembly of claim 1, wherein an end of the ring portion facing the package substrate is inserted into the releasable adhesive layer.

11. The package assembly of claim 1, wherein the ring portion is attached through the package substrate through the releasable adhesive layer.

12. The package assembly of claim 1, wherein the ring portion and the lid portion are integratedly formed.

13. A package assembly, comprising:
a package substrate;
a device package disposed on a side of the package substrate and electrically coupled to the package substrate; and
a support structure coupled to the side of the package substrate to accommodate the device package therein, and the support structure comprising:
a lid portion comprising a transparent material, wherein a first space is between the lid portion and the device package; and
a ring portion vertically between the lid portion and the package substrate, wherein a second space is between the ring portion and the device package and is in spatial communication with the first space.

14. The package assembly of claim 13, wherein the support structure further comprises a releasable adhesive layer attached to the lid portion and the ring portion.

15. The package assembly of claim 14, wherein the transparent material of the lid portion allows a radiation to pass through the lid portion and irradiate the releasable adhesive layer.

16. The package assembly of claim 13, wherein the ring portion comprises the transparent material, and the support structure further comprises a releasable adhesive layer attached to the ring portion and the package substrate.

17. The package assembly of claim 16, wherein the transparent material of the lid portion and the ring portion allows a radiation to pass through the lid portion and the ring portion and irradiate the releasable adhesive layer.

18. A manufacturing method of a package assembly, comprising:
coupling a device package to a side of a package substrate; and
coupling a support structure to the side of the package substrate to accommodate the device package therein, wherein the support structure comprises:
a lid portion made of a material transparent to a radiation;
a ring portion between the lid portion and the package substrate; and
a releasable adhesive layer being response to the radiation.

19. The manufacturing method of claim 18, wherein coupling the support structure to the side of the package substrate comprising:
attaching the ring portion on the side of the package substrate;
forming the releasable adhesive layer on the ring portion; and
disposing the lid portion over the ring portion; and
curing the releasable adhesive layer after disposing the lid portion over the ring portion.

20. The manufacturing method of claim 18, wherein coupling the support structure to the side of the package substrate comprising:
forming the releasable adhesive layer on the side of the package substrate; and
disposing the ring portion and the lid portion on the releasable adhesive layer, wherein the ring portion and the lid portion are integratedly formed.
